(19) United States
(12) Patent Application Publication
(10) Pub. No.: US 2013/0337170 A1
(43) Pub. Date: Dec. 19, 2013

(54) Methods and Apparatus for the Synthesis of Large Area Thin Films

(71) Applicant: Xuesong Li, Wappingers Falls, NY (US)

(72) Inventor: Xuesong Li, Wappingers Falls, NY (US)

(21) Appl. No.: 13/526,598

(22) Filed: Jun. 19, 2012

(51) Int. Cl. C23C 16/458

(52) U.S. Cl. 427/248.1; 118/728

(57) ABSTRACT

The invention provides methods and apparatus for supporting a substrate in a chemical vapor deposition reactor, and methods and apparatus for synthesizing large area thin films. The invention provides a method to coil the substrate into a cylindrical shape with a buffer layer embedded so as to achieve a many-fold increase in the effective width of the substrate. The buffer layer may also provide precursors or reactants for the deposition of the thin film.

### FIELD OF THE INVENTION

The present invention relates broadly to the production of films via chemical vapor deposition, and in particular, to methods and apparatus for forming graphene films and boron nitride films using such deposition.

### BACKGROUND OF THE INVENTION

Graphene and boron-nitride films are examples of useful large area thin films that may be beneficially produced using the methods and apparatus of the present invention. The invention is particularly useful in the synthesis of graphene, an allotrope of carbon with one-atom-thick planar sheet of sp2-bonded carbon atoms that are densely packed in a honeycomb crystal lattice. Graphene has distinctive electrical, mechanical and chemical properties. It is more electrical conductive than silver, more thermal conductive than diamond, and much stronger than steel. In addition, it is almost fully transparent to visual light and chemically stable to most of chemicals at ambient conditions. All of these unique properties make graphene attractive for applications in many fields such as flexible electronics, energy, optielectronics and so on.

Graphene may be formed on the surface of a substrate by a variety of methods. An exemplary but promising method is set forth in U.S. Patent Application Publication No. 2011/0091647, in which, graphene may be produced using a chemical vapor deposition (CVD) process. In a typical CVD process, a given composition, and flow of reactant gases are introduced via an inlet manifold into a reaction space where they are adsorbed onto a substrate. There, the reactants undergo migration and film-forming chemical reactions. The reaction by-products are then desorbed from the substrate and removed from the reaction space via an outlet manifold. Tube furnace CVD systems (horizontal or vertical) are commonly utilized for CVD. In a typical tube furnace CVD system, a cylindrical quartz or alumina process tube is utilized as the reaction chamber. The process tube is surrounded by a heating, furnace comprising resistance-heated heating elements (e.g., heating coils), which is utilized to heat the process tube and thus the substrate located inside the process tube. In a typical CVD process using the tube furnace CVD systems, the chemical reactants are flowed into the process tube from one end of the tube via an inlet manifold and the exhaust comes out from the other end of the process tube via an outlet manifold.

The aforementioned U.S. Patent Application Publication No. 2011/0091647 discloses a CVD process by which graphene may be formed on a metallic substrate such as copper foil, which is heat-treated in the presence of a gaseous carbon source, specifically, a mixture of a hydrocarbon gas and hydrogen gas. The metallic substrate is loaded into the reaction chamber of a tube furnace and reacts with the gaseous sources at a specified temperature It is believed that during the treatment, the hydrocarbon gas, typically methane, is decomposed on the surface of the hot metallic substrate to form a deposit on the substrate as a thin carbon film (gaphene). Hydrogen may be utilized to balance the partial pressure of the hydrocarbon gas and protect graphene from being etched by the oxidants such as water from the background gas. After a specified period of time the heat treatment is terminated, and the furnace, along with the coated substrate, is then cooled to room temperature, after which the thin film may be used directly, with the substrate still stacked, or may be separated or transferred from the substrate in a known manner, and then used.

In a similar manner, thin films of boron-nitride can be obtained by CVD, from precursors such as ammonia borane, using a metallic foil substrate. Moreover, in addition to utilizing conventional CVD, graphene films and boron-nitride films can alternatively be produced using other related processes, such as plasma-enhanced CVD (PECVD), as well as by using similar processes such as atomic layered deposition (ALD).

In each of these production techniques, the size (i.e., the surface area) of the thin film that is produced is determined by the size of the substrate on which it is grown, and the latter is limited, in turn, only by the dimensions of the reactor chamber or cavity of the CVD apparatus that is used. In general, that chamber is a horizontally-oriented cylindrical quartz tube, and the dimensions of the substrate which may be used are circumscribed by the dimensions of the chamber—the length of the substrate, which is defined as the dimension parallel to the axis of the cylindrical chamber, is determined by the length of that portion of the chamber which can be heated (that is, by the length of the heating zone of the furnace), and the width of the substrate, which is defined as the dimension perpendicular to the length, is determined by the diameter of the chamber (that diameter being about equal to the maximum substrate width that can be obtained when the conventional technique of placing a flat sheet of the substrate into the cylindrical chamber is utilized). Although there are relatively few technical difficulties involved in manufacturing very long quartz tubes, e.g., several or tens of meters or more, and in manufacturing tube furnaces that would accommodate such tubes, the difficulty in manufacturing larger diameter quartz tubes increases dramatically with the increase in diameter of the tube. In addition, the connections between the quartz tube and the surrounding metal parts become more problematic with increased diameters because the manufacturing errors in the size and/or roundness of the quartz tube become magnified. Therefore, there are practical limits as to the diameter of the quartz tube reactor chamber, which in turn limit the width of the substrate that may be utilized therein.

Accordingly, a technique by which to load a metallic foil substrate into the quartz tube reactor chamber, such that the width of the substrate, and therefore the width of the film subsequently produced, can be increased dramatically despite the limits imposed by the diameters of presently-existing reactor chambers for CVD furnaces, would be a useful addition to the technology by which such films are manufactured using CVD or similar processes. Yet, despite the existence and availability of CVD processes for many years, such a technique has eluded researchers.

Although efforts have been made in the prior art to provide such techniques, those efforts have met with only very limited success. For examples, the prior art includes a technique by which the substrate can be wrapped around a cylindrical holder, but this provides an increase in substrate width of only about three times that of the chamber diameter itself.

It therefore the principal object of the present invention to provide improved methods and apparatus for synthesizing large area thin films using a CVD or CVD-type furnace, in which the width dimension of the thin film produced may be greatly increased.

It is another object of the present invention to provide improved methods and apparatus of providing precursors or reactants for synthesizing films in the reactor chamber of a CVD or CVD-type furnace.

### SUMMARY OF THE INVENTION

These and other objects of the present invention are achieved by coiling a metallic substrate into a cylindrical body embedded with a buffer layer. Compared to placing a flat sheet of the substrate into the cylindrical chamber or swapping the substrate around a cylindrical holder, the coiled substrate cylinder utilizes the space inside the reactor chamber more efficiently and achieves a significant increase in the effective width of the substrate. The embedded buffer layer is critical since the layers of the metallic substrate coil may contact one another and stick together at high temperature if there is no such a buffer layer in between those metallic layers and thus the metallic substrate coil may not be uncoiled after CVD. For this reason, a buffer layer, which is not smaller than the metallic substrate in both length and width, is utilized to separate the layers of the metallic substrate coil and the buffer layer should satisfy the criteria that it should not stick to the metallic substrate or poison the synthesis of the film. In some embodiments of this invention, some kinds of buffer layers may also be utilized as a source of precursors or reactants for the synthesis of film using CVD. The sizes of the buffer layer and the metallic substrate are also adapted so that the final coiled metallic substrate cylinder may be placed within their conventional cylindrical reaction chamber of a CVD or CVD-type furnace.

Thus, one aspect of the present invention generally concerns materials or apparatus utilized as a buffer layer. In one embodiment of this aspect, carbon fiber woven sheet or cloth are utilized as a buffer layer for separating the layers of the metallic substrate coil for synthesizing a large area graphene film using CVD.

In another embodiment of this aspect of the invention, other cloth (or textile or fabric), typically woven with natural fibers such as wool, cotton or silk, or artificial fibers such as nylon or rayon, are utilized as a buffer layer for separating the layers of the metallic substrate coil for synthesizing a large area graphene film using CVD.

In another embodiment of this aspect of the invention, paper, typically made from cellulose, is utilized as a buffer layer for separating the layers of the metallic substrate coil for synthesizing a large area graphene film using CVD.

In another embodiment of this aspect of the invention, a string of parallel aligned quartz tubes or rods is utilized as a buffer layer for separating the layers of the metallic substrate coil for synthesizing a large area thin film using CVD. In particular, this apparatus is utilized not only for synthesizing graphene films but also for synthesizing boron nitride films.

Another aspect of the invention generally concerns improved methods for providing precursors or reactants for the synthesis of large area thin film using CVD. In one embodiment of this aspect of the present invention, aforementioned buffer layers (carbon fiber sheet or cloth, cloth woven with wool, cotton, silk, nylon, or rayon, and paper) except the string of quartz tubes or rods may release carbon atoms at high temperature and thus may be also utilized as a source of carbon for synthesizing graphene film on a metallic substrate using CVD. With the use of this pre-embedded carbon source, no other reactant source is required, which indicates that no gas inlet is required and thus the CVD apparatus is simplified compared to the CVD apparatus described in the U.S. Patent Application Publication No. 2011/0091647.

### BRIEF DESCRIPTION OF THE DRAWINGS

These and other aspects, features, objects and advantages of the present invention will become more apparent to those skilled in the art from the following detailed description of the presently most preferred embodiments thereof (which are given for the purposes of disclosure), when read in conjunction with the accompanying drawings (which form a part of the specification, but which are not to be considered as limiting its scope), wherein:

FIG. 1A is a schematic perspective view depicting the stack of the substrate and the buffer layer prior to coiling, as well as a tube used to effectuate the coiling;

FIG. 1B is a schematic perspective view depicting the coiling of the stack of the substrate and the buffer layer into a cylindrical body;

FIG. 1C is a schematic perspective view showing the coiled cylindrical body of the metallic substrate embedded with, the buffer layer and with the tube as the core;

FIG. 2 is a schematic perspective view showing a string of parallel aligned quartz tubes or rods;

FIG. 3A is a diagrammatic view depicting the conventional process by which a thin film such as graphene is deposited on a surface of a flat substrate in the reactor chamber of a CVD device;

FIG. 3B is a diagrammatic view depicting the conventional process by which a thin film such as graphene is deposited on a surface of a coiled substrate in the reactor chamber of a CVD device;

FIG. 3C is a diagrammatic view depicting the process by which a thin film such as graphene is deposited on a surface of a coiled substrate and by using the pre-embedded buffer layer as the reactant source in the reactor chamber of a CVD device without the gas inlet;

FIG. 4A is a greatly enlarged schematic cross-sectional view of a portion of the coiled cylindrical body (when the embedded buffer layer is a sheet) following the deposition of a thin film on to both surfaces of the substrate.

FIG. 4B is a greatly enlarged schematic cross-sectional view of a portion of the coiled cylindrical body (when the buffer layer is a string of tubes or rods) following the deposition of a thin film on to both surfaces of the substrate.

### DETAILED DESCRIPTION OF THE INVENTION

The present invention will be described with reference to illustrative embodiments. For this reason, numerous modifications can he made to these embodiments and the results will still come within the scope of the invention. No limitations with respect to the specific embodiments described herein are intended or should be inferred.

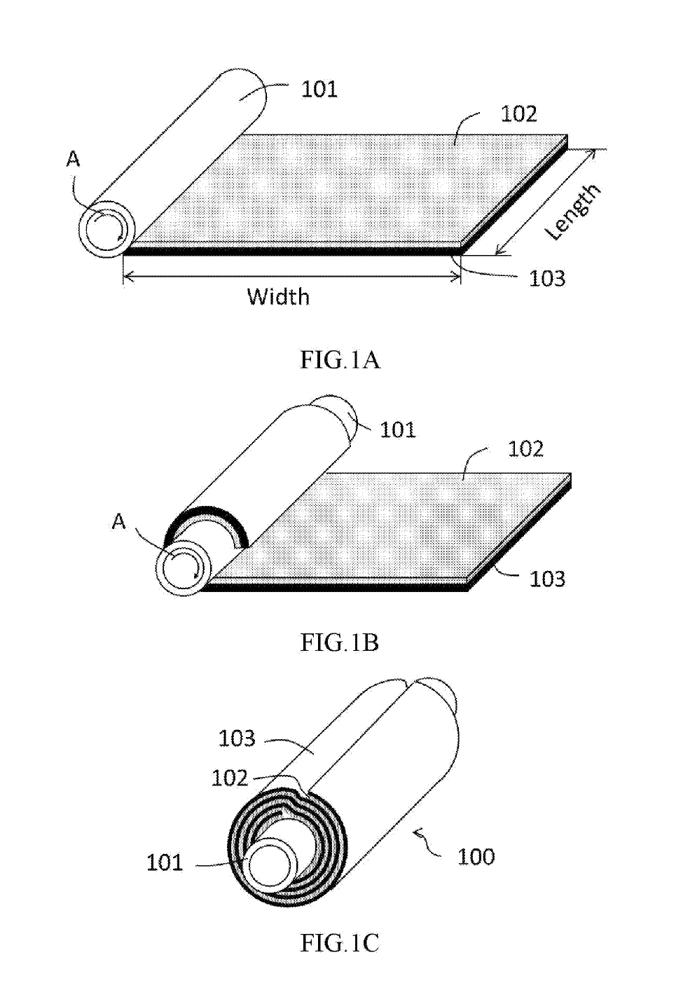

Referring to FIGS. 1A-C, FIGS. 1A-C schematically depict the manner in which the metallic substrate and the buffer layer are stacked and then rolled up or coiled into a cylindrical shape by a tube or rod in accordance with an embodiment of the present invention. Firstly, as shown in FIG. 1A, a buffer layer 102 is stacked on a metallic substrate 103. The length, and width of the buffer layer 102 are preferred not less than the length and width of the metallic substrate 103. The thickness of the buffer layer 102 may vary from 1 micrometer to a few millimeters. Then, a tube or rod 101 with a diameter ranging from a few millimeters to a few centimeters, commonly made of quartz (or graphite or alumina) and preferred longer than the length of the stack, is attached at one edge of the length side. This attachment may be achieved, e.g., by fixing the two corners of the edge of the stack on the tube with tapes (not shown), which may be taken off after coiling. Then, as illustrated in FIG. 1B, the stack is coiled by grasping the extended portions of the tube on either side, and by rotating it (e.g., by spinning, winding or twirling), in the direction indicated by the arrow A in FIGS. 1A and B. After coiling, the tube or rod is left in the core of the cylinder as a supporter or holder and the tapes fixing the stack on the tube are taken off, as shown in FIG. 1C.

In one embodiment, the buffer layer 102 may be carbon fiber woven sheet or cloth for synthesizing graphene film on a metallic substrate using CVD. Carbon fiber, also called graphite fiber, is usually with a diameter of about 5-10 μm and composed mostly of carbon atoms. The carbon atoms are bonded together in crystals that are more or less aligned parallel to the long axis of the fiber. Several thousand carbon fibers are bundled together to form a tow, which may be used by itself or woven into a sheet or cloth. The thickness of carbon fiber sheet or cloth may be ranging from several hundred of micrometers to several millimeter.

In another embodiment, the buffer layer 102 may be other cloth (or textile or fabric) woven with natural fibers such as wool, cotton or silk, or artificial fibers such as nylon or rayon for synthesizing graphene film on a metallic substrate using CVD. Although these cloth (or textile or fabric) may be thermally decomposed when it is heated up to several hundred of Celsius degrees, there may be still enough char to keep its, layer form to use as a buffer layer. The thickness of cloth (or textile or fabric) may be ranging from tens of micrometers to several millimeters.

In another embodiment, the buffer layer 102 may be paper for synthesizing graphene film on a metallic substrate using CVD. Paper is mainly composed of cellulose, which is an organic compound with the formula (C₆H₁₀O₅)ₙ. Although paper may be thermally decomposed when it is heated up to several hundred of Celsius degrees, there may be still enough char to keep its layer form to use as a buffer layer. The thickness of paper may be ranging from tens of micrometers to hundreds of micrometers.

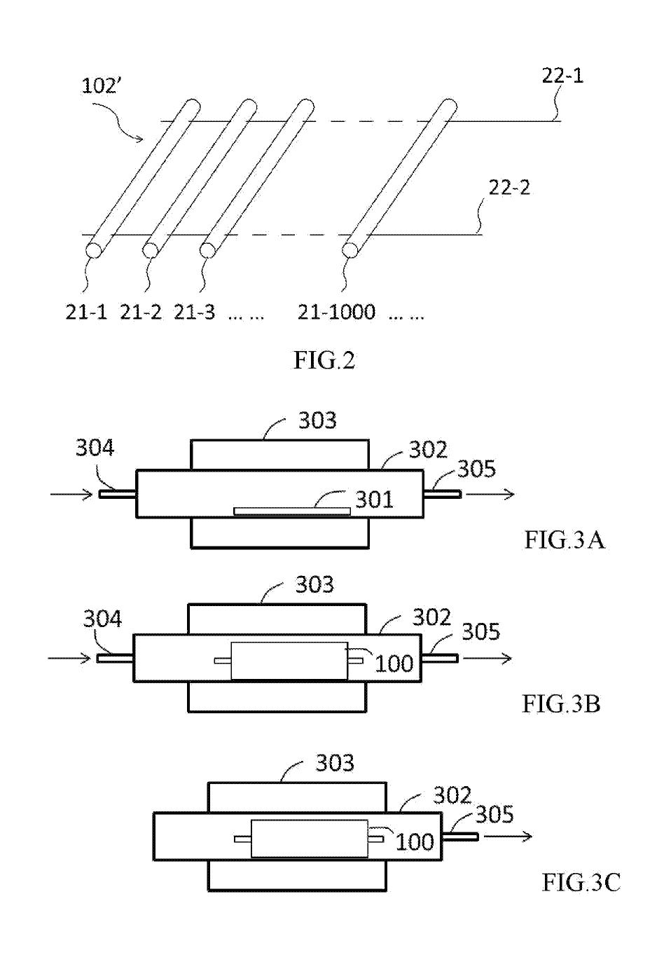

In another embodiment, referring to FIG. 2, the buffer layer 102 may be also a string of parallel aligned quartz tubes or rods, which is numbered as 102′ so as to differentiate from the aforementioned sheet-like buffer layers. The diameter of the quartz tubes or rods (21-1, 21-2, 21-3, . . . 21-1000 . . . ) may be ranging from 1 millimeter to several millimeters. The inter distance among the quartz tubes or rods (21-1, 21-2, 21-3, . . . 21-1000 . . . ) may be ranging from tens of micrometers to several millimeters. These quartz tubes or rods (21-1, 21-2, 21-3, . . . 21-1000 . . . ) are strung together by two metal (e.g., copper or nickel) wires 22-1 and 22-2. The diameter of the metal wires 22-1 and 22-2 may be ranging from hundreds of micrometers to several millimeters. The distance between the two metal wires 22-1 and 22-2 is preferred larger than the length of the metallic substrate so that the substrate stacks on the tubes or rods in between the two metal wires 22-1 and 22-2 without attaching them. It should be noted that buffer layer 102′ may be utilized both for synthesizing graphene films and for synthesizing boron nitride films.

Referring to FIG. 3A, the conventional prior art process by which a thin film such as graphene may be deposited on a surface of a flat substrate 301 in the reactor chamber 302 of a CVD furnace 303 having a gas inlet 304 and a gas outlet 305, in the manner described generally in U.S. Patent Application Publication No. 2011/0091647, is depicted diagrammatically, but for ease of illustration, the substrate holder, heating elements and other components of a conventional CVD furnace have been omitted.

Referring to FIG. 1C and FIG. 3B, in one embodiment in accordance with the present invention, FIG. 3B diagrammatically depicts a process similar to that described generally in U.S. Patent Application Publication No. 2011/0091647 by which a thin film such as graphene and boron nitride may be deposited on a surface of a coiled substrate 101 embedded with a buffer layer 102 in the reactor chamber 302 of a CVD furnace 303 having a gas inlet 304 and a gas outlet 305, but for ease of illustration, the heating elements and other components of a conventional CVD, furnace have been omitted.

Referring to FIG. 3C, in another embodiment, since the aforementioned buffer layers (carbon fiber sheet or cloth, cloth woven with wool, cotton, silk, nylon, or rayon, and paper mainly composed of cellulose) except the string of quartz tubes or rods may release carbon atoms at high temperature, they may be also utilized as a source of carbon for synthesizing graphene film on a metallic substrate using CVD. With the use of this pre-embedded carbon source, no other source is required, which indicates that no gas inlet 304 is required and thus the CVD apparatus is simplified compared to the CVD apparatus described in the U.S. Patent Application Publication No. 2011/0091647 as depicted diagrammatically in FIG. 3C.

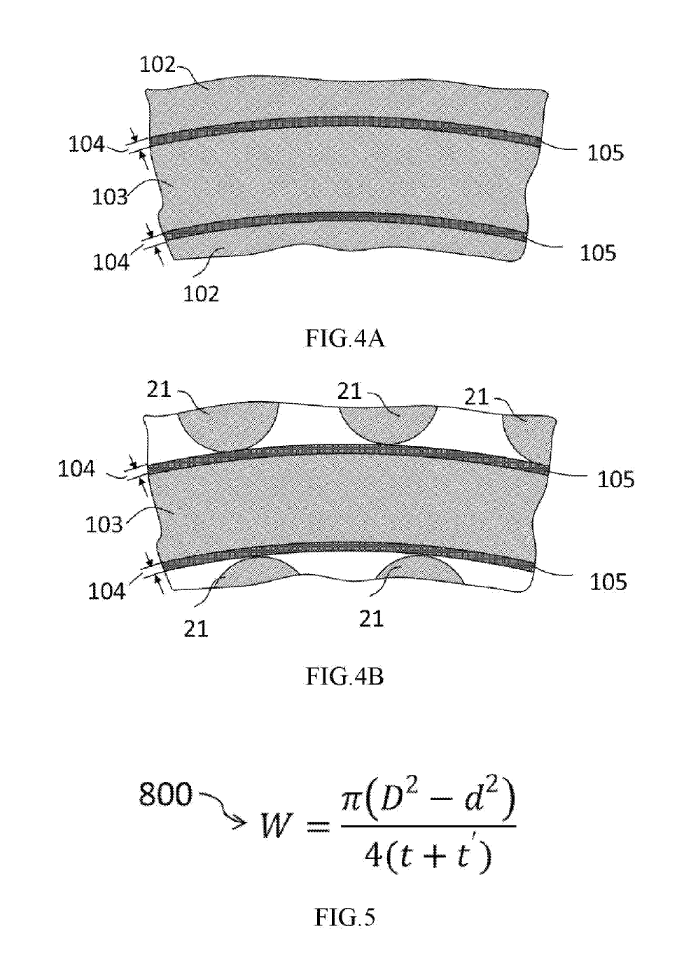

Referring now to FIGS. 4A and B in addition to the aforementioned FIGS. 1 and 2, although the metallic substrate 103 is stacked with a buffer layer 102 or 102′ such that, to the naked eye, there does not appear to be a gap between the metallic substrate 103 and the buffer layer 102 or each tube or rod element 21 in the buffer layer 102′, those of skill in the art will understand that a microscopic gap 104 will always exist which will be sufficient to enable a thin film coating 105 to form during the CVD process on the surface of the metallic substrate 103 that is proximal to the surface of the buffer layer 102 or each tube or rod element 21 in the buffer layer 102′, as illustrated in FIGS. 4A and B. Thus, when subjected to a CVD process, a continuous film coating 105 will be formed across the entire area and on both surfaces of the substrate 103, even though the latter is wrapped around successive buffer layer 102 or discrete tube or rod elements 21 in the buffer layer 102′ during the CVD process, as illustrated in FIGS. 4A and B.

In one embodiment, in addition to referring to FIG. 1, the metallic substrate 103 can be easily separated from the buffer layer 102 or 102′ by simply uncoiling the metallic substrate and buffer layer cylinder 100 in a reverse way and peeling off the buffer layer 103, following the deposition of a thin film coating using a CVD process. Then the deposited film may be used directly, with the substrate still stacked, or may be separated or transferred from the substrate in a known manner, and then used.

As mentioned above and referring to FIGS. 1 and 2, the maximum width of the substrate 103 that can be loaded into a cylindrical reaction chamber, and therefore the width of the thin film subsequently produced can be calculated by referring to the equation 800 shown in FIG. 5. Wherein W is the maximum width of the substrate 103 that can be loaded into a cylindrical reaction chamber, and therefore the width of the thin film subsequently produced; D is the inner diameter of the cylindrical reaction chamber, d is the out diameter of the tube or rod 101 to coil the metallic substrate and buffer layer stack; t is the thickness of the buffer layer 102 or 102′ (the thickness of the buffer layer 102′ is equal to the diameter of the quartz tube or rod 21); t′ is the thickness of the substrate 103. In one embodiment, take D=46 mm, d=10 mm, t=0.5 mm, t′=0.075 mm, then the width of the thin film produced, W=2752 mm, ˜60 times of the diameter of the reaction chamber. In an alternative embodiment of the invention, take D=125 mm, d=10 mm, t=0.5 mm, t′=0.075 mm, then the width of the thin film produced, W=˜21 meters, ˜170 times of the diameter of the reaction chamber. Hence, the invention provides methods and apparatus for forming graphene films and other thin films that have a greatly enhanced width dimension.

While there has been described what are at present considered to be the preferred embodiments of the present invention, it will be apparent to those skilled in the art that the embodiments described herein are by way of illustration and not of limitation. Various modifications of the disclosed embodiments, as well as alternative embodiments of the invention, will become apparent to persons skilled in the art upon reference to the description of the invention. Therefore, it is to be understood that various changes and modifications may be made in the embodiments disclosed herein without departing from the true spirit and scope of the present invention, as set forth in the appended claims, and it is contemplated that the appended claims will cover any such modifications or embodiments.

1. A method for synthesizing a thin film, the method comprising the steps of
(a) providing a buffer layer to stack on a substrate for thin film synthesis;
(b) utilizing a tube or rod to coil said substrate and buffer layer stack into a cylindrical shape;
(c) positioning said coiled cylinder in a processing chamber and forming a thin film on a surface of the substrate by CVD;
(d) unloading the substrate from said coiled cylinder.

2. The method of claim 1 wherein said buffer layer may be:
carbon fiber sheet or cloth;
other cloth (or textile or fabric) woven with natural fibers (such as wool, cotton or silk) or artificial fibers (such as nylon or rayon);
paper composed of mainly cellulose;
or a string of quartz tubes or rods.

3. The method of claim 1 wherein said tube or rod to effectuate the coiling is made of quartz or graphite or alumina.

4. The method of claim 1 wherein the thin film is selected from the group consisting of graphene and boron nitride.

5. A method for supporting a substrate in a processing chamber for depositing a CVD coating, the method comprising the steps of
(a) providing a buffer layer to stack on a substrate for thin film synthesis;
(b) utilizing a tube or rod to coil said substrate and buffer layer stack into a cylindrical shape;
(c) positioning said coiled cylinder in a processing chamber and depositing a CVD coating onto a surface of the substrate.

6. The method of claim 5 wherein said buffer layer may be:
carbon fiber sheet or cloth;
other cloth (or textile or fabric) woven with natural fibers (such as wool, cotton or silk) or artificial fibers (such as nylon or, rayon);
paper composed of mainly cellulose;
or a string of quartz tubes or rods.

7. The method of claim 5 wherein said tube or rod to effectuate the coiling is made of quartz or graphite or alumina.

8. The method of claim 5 wherein the thin film is selected from the group consisting of graphene and boron nitride.

9. In a method for synthesizing a thin, film using CVD, said method comprising the steps of heating a substrate, depositing a thin film onto a surface of the substrate by exposing the substrate to CVD, cooling the substrate to room temperature, the improvement comprising, providing prior to said heating step loading a substrate by utilizing a tube or rod to coil the substrate stacked with a buffer layer into a cylindrical, shape, the improvement further comprising uncoiling the substrate from said coiled cylinder subsequent to said deposition step.

10. The method of claim 9 wherein said buffer layer may be:
carbon fiber sheet or cloth;
other cloth (or textile or, fabric) woven with natural fibers (such as wool, cotton or silk) or artificial fibers (such as nylon or rayon);
paper composed of mainly cellulose;
or a string of quartz tubes or rods.

11. The method of claim 9 wherein said tube or rod to effectuate the coiling is made of quartz or graphite or alumina.

12. The method of claim 9 wherein the thin film is selected from the group consisting of graphene and boron nitride.

13. In a method for synthesizing a graphene film using CVD, said method comprising the steps of heating a substrate, depositing a graphene film onto a surface of the substrate by exposing the substrate to CVD, cooling the substrate to room temperature, the improvement comprising, providing prior to said heating step loading a substrate by utilizing a tube or rod to coil the substrate stacked with a buffer layer into a cylindrical shape, the improvement also comprising providing carbon source by the buffer layer instead of by a gas fed through the gas inlet for depositing the graphene film, the improvement further comprising uncoiling the substrate from said coiled cylinder subsequent to said deposition step.

14. The method of claim 13 wherein said buffer layer may be:
carbon fiber sheet or cloth;
other cloth (or textile or fabric) woven with natural fibers (such as wool, cotton or silk) or artificial fibers (such as nylon or rayon);
or paper composed of mainly cellulose.

15. The method of claim 13 wherein said tube or rod to effectuate the coiling is made of quartz or graphite or alumina.

16. An apparatus for processing a substrate comprising
(a) a processing chamber;
(b) a coiled substrate cylinder embedded with a buffer layer and a core of tube or rod disposed within said processing chamber.

17. The apparatus of claim 16 wherein said coiled substrate cylinder embedded with a buffer layer achieved by utilizing a tube or rod to coil a substrate stacked with a buffer layer into a cylindrical shape.

18. The apparatus of claim 16 wherein the substrate is processed to deposit a thin film thereon, and wherein the thin film is selected from the group consisting of graphene and boron nitride.

19. The method of claim 16 wherein said buffer layer may be:
carbon fiber sheet or cloth;
other cloth (or textile or fabric) woven with natural fibers (such as wool, cotton or silk) or artificial fibers (such as nylon or rayon);
paper composed of mainly cellulose;
or a string of quartz tubes or rods.

20. The apparatus of claim 16 wherein said tube or rod core is made of quartz or graphite or alumina.
